(19) United States
(12) Patent Application Publication
(10) Pub. No.: US 2025/0015064 A1
(43) Pub. Date: Jan. 9, 2025

(54) SEMICONDUCTOR DEVICE AND METHOD FOR FABRICATING THE SAME

(71) Applicant: Samsung Electronics Co., Ltd., Suwon-si (KR)

(72) Inventors: Yoon Young JEON, Suwon-si (KR); Young Min KIM, Suwon-si (KR); Ji Hyun LIM, Suwon-si (KR)

(73) Assignee: Samsung Electronics Co., Ltd., Suwon-si (KR)

(21) Appl. No.: 18/433,777

(22) Filed: Feb. 6, 2024

(30) Foreign Application Priority Data
Jul. 6, 2023 (KR) 10-2023-0087749

(51) Int. Cl. H01L 25/16; H01L 21/48; H01L 23/00; H01L 23/498; H01L 23/538; H10B 80/00

(52) U.S. Cl. CPC H01L 25/16; H01L 21/4857; H01L 23/49816; H01L 23/49822; H01L 23/49838; H01L 23/5386; H01L 24/08; H01L 24/16; H01L 24/32; H01L 24/73; H01L 28/40; H10B 80/00; H01L 2224/08235; H01L 2224/16227; H01L 2224/32225; H01L 2224/73204; H01L 2924/1433; H01L 2924/15153; H01L 2924/15174; H01L 2924/19041

(57) ABSTRACT

A semiconductor device is described, in which a multi-bridge is packaged in a substrate to improve a small form factor. The semiconductor device comprises a substrate including a first surface and a second surface, which face each other, and defining a first cavity passing through the first surface and the second surface, a first redistribution layer structure formed on the first surface of the substrate, a second redistribution layer structure formed on the second surface of the substrate, a connection terminal disposed on the second redistribution layer structure, and a multi-bridge packaged in the first cavity, including a first bridge facing the first surface and electrically connected to the first redistribution layer structure and a second bridge facing the second surface and electrically connected to the second redistribution layer structure.

### CROSS-REFERENCE TO RELATED APPLICATION

This application claims priority from Korean Patent Application No. 10-2023-0087749 filed on Jul. 6, 2023 in the Korean Intellectual Property Office and all the benefits accruing therefrom under 35 U.S.C. 119, the contents of which in its entirety are herein incorporated by reference.

### BACKGROUND

### Technical Field

Inventive concepts relate to a semiconductor device, and a method for fabricating the same.

### Description of the Related Art

In order to implement or improve a small form factor of semiconductor device, it is beneficial to package multi-chips and multi-components in a limited space. For example, semiconductor chips may be packaged in a package substrate, so that the limited space may be efficiently used.

### SUMMARY

Example embodiments of inventive concepts relate to a semiconductor device that implements or improves a small form factor by packaging a multi-bridge in a substrate, and a method for fabricating the same.

Example embodiments of inventive concepts are not limited to the example embodiments mentioned above, and other example embodiments not mentioned will be clearly understood by those ordinarily skilled in the art from the following description.

According to some example embodiments of inventive concepts, described is a semiconductor device comprising: a substrate having a first surface and a second surface facing each other, and defining a first cavity passing through the first surface and the second surface, a first redistribution layer structure on the first surface of the substrate, a second redistribution layer structure on the second surface of the substrate, a connection terminal on the second redistribution layer structure, and a multi-bridge in the first cavity, the multi-bridge including a first bridge directed toward the first surface and electrically connected to the first redistribution layer structure and a second bridge directed toward the second surface and electrically connected to the second redistribution layer structure.

According to some example embodiments of inventive concepts, described is a semiconductor device comprising: a substrate having a first surface and a second surface facing each other, and defining a first cavity and a second cavity, the first cavity and second cavity passing through the first surface and second surfaces; a first redistribution layer structure on the first surface of the substrate; a second redistribution layer structure on the second surface of the substrate; a connection terminal on the second redistribution layer structure; a multi-bridge in the first cavity, the multi-bridge including a first bridge directed toward the first surface and electrically connected to the first redistribution layer structure, a second bridge directed toward the second surface and electrically connected to the second redistribution layer structure, and an adhesive film between the first bridge and the second bridge; first and second elements on the first redistribution layer structure, the first and second elements configured to transmit and receive signals to and from each other through the first bridge; a component on the second redistribution layer structure and electrically connected to the second bridge; and a third element in the second cavity.

According to some example embodiments of inventive concepts, described is a method for fabricating a semiconductor device comprising: fixing a substrate onto a first carrier, the substrate having a first surface and a second surface facing each other, and defining a first cavity passing through the first surface and the second surface, the first surface being directed toward the first carrier, packaging a multi-bridge, which includes a first bridge directed toward the first surface and a second bridge directed toward the second surface, in the first cavity; forming a second redistribution layer structure on the second surface of the substrate, removing the first carrier; fixing the substrate onto a second carrier, the second surface being directed toward the second carrier; and forming a first redistribution layer structure on the first surface of the substrate.

Details of the other embodiments are included in the detailed description and drawings.

### BRIEF DESCRIPTION OF THE DRAWINGS

The above and other aspects and features of inventive concepts will become more apparent by describing in detail example embodiments thereof with reference to the attached drawings, in which:

FIG. 1 is a plan view illustrating a semiconductor device according to some embodiments of inventive concepts;

FIG. 2 is a conceptual cross-sectional view illustrating a semiconductor device, which is taken along line A-A of FIG. 1;

FIG. 3 is a detailed view of the cross-sectional view of FIG. 2;

FIG. 4 is a view illustrating an example of a multi-bridge shown in FIG. 2;

FIG. 5 is a view illustrating another example of a multi-bridge shown in FIG. 2;

FIG. 6 is a plan view illustrating a semiconductor device according to some example embodiments of inventive concepts;

FIG. 7 is a cross-sectional view illustrating a semiconductor device, which is taken along line B-B of FIG. 6;

FIG. 8 is a cross-sectional view illustrating a semiconductor device according to some example embodiments of inventive concepts;

FIG. 9 is a cross-sectional view illustrating a semiconductor device according to some example embodiments of inventive concepts;

FIG. 10 is a flow chart illustrating a method for fabricating a semiconductor device according to some example embodiments of inventive concepts; and

FIGS. 11 to 13 are views illustrating intermediate steps to describe the method of FIG. 10.

### DETAILED DESCRIPTION

Hereinafter, non-limiting example embodiments according to inventive concepts will be described in detail with reference to the accompanying drawings. The same reference numerals will be used for the same elements on the drawings, and a repeated description of the corresponding elements will be omitted.

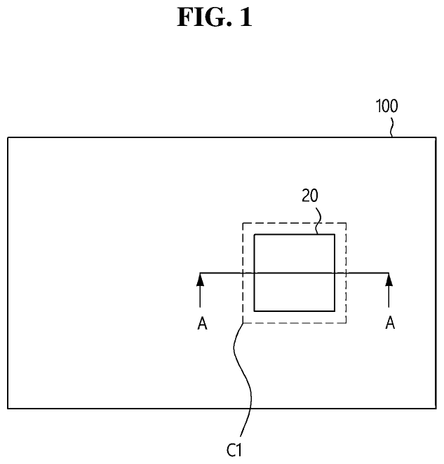

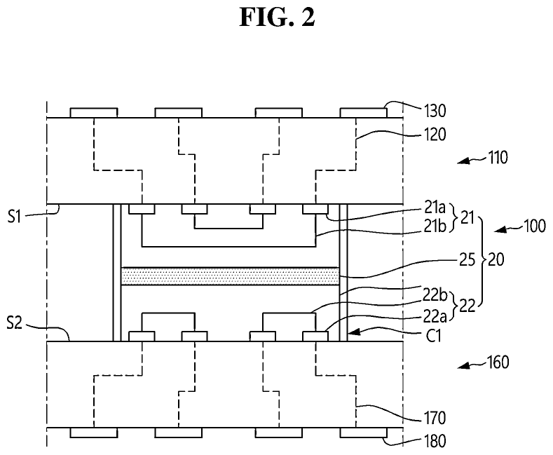

FIG. 1 is a plan view illustrating a semiconductor device according to some example embodiments of inventive concepts. FIG. 2 is a conceptual cross-sectional view illustrating a semiconductor device, which is taken along line A-A of FIG. 1.

Referring to FIGS. 1 and 2, the semiconductor device according to some example embodiments of inventive concepts includes a substrate 100, a first redistribution layer structure 110, a second redistribution layer structure 160, and a multi-bridge 20.

The substrate 100 includes a first surface S1 and a second surface S2, which face each other. The substrate 100 includes a first cavity C1 passing through the first surface S1 and the second surface S2.

Although the substrate 100 is not shown in full detail, the substrate 100 may include, for example, an embedded trace substrate (ETS). The ETS may be a circuit board in which a circuit pattern is embedded in an insulating material. Since the ETS may have a coreless structure, it is possible to implement a fine circuit without increasing costs, and it is easier to enable a layer-down design (for example, a four-layer circuit board may be designed as a three-layer circuit board).

The multi-bridge 20 includes a first bridge 21 directed toward the first surface S1, a second bridge 22 directed toward the second surface S2, and an adhesive film 25 disposed between the first bridge 21 and the second bridge 22. The adhesive film 25 may be a die attach film (DAF), but example embodiments are not limited thereto.

The first bridge 21 includes a first wiring pattern 21b formed inside a die, and a first bridge pad 21a on a surface of the die. The first wiring pattern 21b serves as a bridge for connecting adjacent first bridge pads 21a to each other. The first bridge 21 is directed toward or associated with the first surface S1, which may mean that the first bridge pad 21a is at the first surface S1. The first wiring pattern 21b shown in FIG. 2 is shown according to an example embodiment, and example embodiments are not limited thereto.

Similarly, the second bridge 22 includes a second wiring pattern 22b formed inside the die, and a second bridge pad 22a exposed to a surface of the die. The second wiring pattern 22b serves as a bridge for connecting adjacent second bridge pads 22a to each other. The second bridge 22 is directed toward or associated with the second surface S2, which may mean that the second bridge pad 22a is at the second surface S2. The second wiring pattern 22b shown in FIG. 2 is shown according to an example embodiment, and example embodiments are not limited thereto.

In addition, the first redistribution layer structure 110 and the second redistribution layer structure 160 are respectively formed on the first and second surfaces of the substrate 100, such that a fan-out package may be configured.

The first redistribution layer structure 110 is formed on the first surface S1 of the substrate 100. The first redistribution layer structure 110 includes a plurality of first pads 130, and a first connection wiring 120 connected to the plurality of first pads 130. At least one of the plurality of first pads 130 is electrically connected to the first bridge pad 21a of the first bridge 21.

The second redistribution layer structure 160 is formed on the second surface S2 of the substrate 100. The second redistribution layer structure 160 includes a plurality of second pads 180, and a second connection wiring 170 connected to the plurality of second pads 180. At least one of the plurality of second pads 180 is electrically connected to the second bridge pad 22a of the second bridge 22.

A plurality of elements (e.g., a memory chip, etc.) may be installed on the first redistribution layer structure 110, and at least one component (e.g., at least one of a capacitor, a resistor, a memristor, an inductor, etc.) may be installed on the second redistribution layer structure 160. As described above, the multi-bridge 20 is packaged in the first cavity C1, so that various elements and/or components may be disposed on various surfaces of the substrate 100 (for example, the first and second surfaces of the substrate, or sides of the redistribution layer structures 110 and 160) to implement various functions within a limited structure, but example embodiments are not limited thereto.

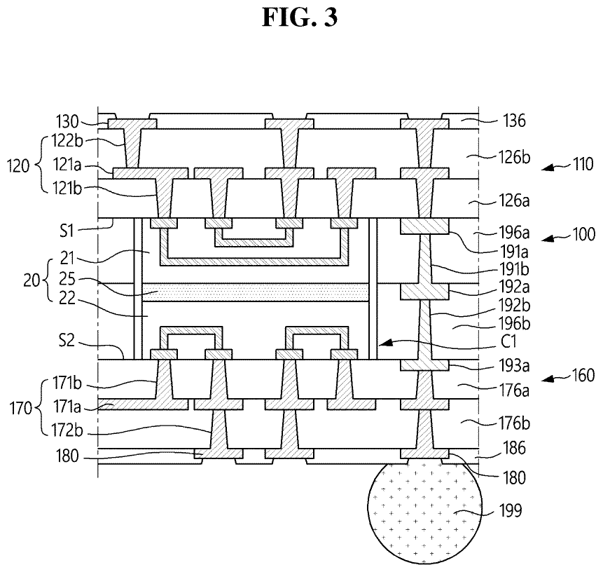

FIG. 3 is a detailed view of the cross-sectional view of FIG. 2. For convenience of description, the following description will be based on differences from the description made with reference to FIGS. 1 and 2.

Referring to FIG. 3, the substrate 100 may include a plurality of insulating layers 196a and 196b, a plurality of via layers 191b and 192b, and a plurality of wiring layers 191a, 192a and 193a.

The plurality of insulating layers 196a and 196b may include an insulating material, and examples of the insulating material may include, for example, at least one of a thermosetting resin such as an epoxy resin or a thermoplastic resin such as polyimide. In addition, for example, a material in which an inorganic filler such as silica and a reinforcing material such as fiberglass are contained (for example, in the resins descried above) may be used as the insulating material. For example, prepreg and Ajinomoto Build-up Film (ABF) may be used as the insulating material, but example embodiments are not limited thereto. The ABF may be provided in the form of resin coated copper (RCC), but is example embodiments are not limited thereto. As occasion demands, a photosensitive material, such as photo imageable dielectric (PIE), may be used, but example embodiments are not limited thereto.

The plurality of wiring layers 191a, 192a and 193a may include, for example, at least one of a metal material such as copper (Cu), aluminum (Al), silver (Ag), tin (Sn), gold (Au), nickel (Ni), lead (Pb), titanium (Ti), or alloy thereof. The plurality of wiring layers 191a, 192a and 193a may perform various functions depending on design. For example, the wiring layers 191a, 192a and 193a may include a ground pattern, a power pattern and a signal pattern. Each of these patterns may be in the form of a line, a plane or a pad. The plurality of wiring layers 191a, 192a and 193a may be formed by a plating process such as Additive Process (AP), Semi AP (SAP), Modified SAP (MSAP) and Tenting (TT), but are not limited thereto.

A metal material may be included in the plurality of via layers 191b and 192b, and the same or substantially the same material as that of the plurality of wiring layers 191a, 192a and 193a may be used as the plurality of via layers 191b and 192b. The plurality of via layers 191b and 192b may include, for example, one or more of a signal via, a ground via, a power via, etc. depending on design. Each of the plurality of via layers 191b and 192b may have, for example, a via hole completely filled with a metal material, or, for example, the metal material may be formed along a wall surface of the via hole. The plurality of via layers 191b and 192b may be formed by a plating process, for example, a process such as AP, SAP, MSAP and TT, but example embodiments are not limited thereto.

The first cavity C1 is formed in the substrate 100, and the multi-bridge 20 is packaged in the first cavity C1. The first bridge 21 of the multi-bridge 20 is electrically connected to the first redistribution layer structure 110, and the second bridge 22 is electrically connected to the second redistribution layer structure 160.

The first redistribution layer structure 110 formed on the first surface S1 of the substrate 100 may include a plurality of insulating layers 126a and 126b, a first protective layer 136, a plurality of first redistribution layers 121a, a plurality of first redistribution vias 121b and 122b, and a plurality of first pads 130. The first connection wiring 120 may include the first redistribution layer 121a, and the first redistribution vias 121b and 122b.

The second redistribution layer structure 160 formed on the second surface S2 of the substrate 100 includes a plurality of insulating layers 176a and 176b, a second protective layer 186, a plurality of second redistribution layers 171a, a plurality of second redistribution vias 171b and 172b, and a plurality of second pads 180. The second connection wiring 170 may include the second redistribution layer 171a, and the second redistribution vias 171b and 172b, but example embodiments are not limited thereto.

The insulating layers 176b, 176a, 126b, and 126a may be vertically stacked, and may include, for example, an insulating resin. The insulating resin may include, for example, one or more of a thermosetting resin such as an epoxy resin, a thermoplastic resin such as polyimide, or a resin in which an inorganic filler and/or a glass fiber (glass cloth or glass fabric) is immersed in the above resins, for example, prepreg, Ajinomoto Build-up Film (ABF), FR-4 and Bismaleimide Triazine (BT). For example, the insulating layers 126a, 126b, 176a and 176b may include a photosensitive resin such as a photoimageable dielectric (PID) resin. The insulating layers 126a, 126b, 176a and 176b may be formed to be thin, and the redistribution layers 121a and 171a and the redistribution vias 121b, 122b, 171b and 172b may be formed of a fine pitch. Boundaries among the insulating layers 126a, 126b, 176a and 176b of different levels may be unclear depending on processes of formation, but example embodiments are not limited thereto.

The redistribution layers 121a and 171a may be disposed on the insulating layers 126a and 176a. The redistribution layers 121a and 171a and the pads 130 and 180 may be electrically connected to each other through the redistribution vias 121b, 122b, 171b and 172b passing through the insulating layers 126a, 126b, 176a and 176b.

The redistribution layers 121a and 171a and the redistribution vias 121b, 122b, 171b and 172b may include, for example, a metal material containing copper (Cu), aluminum (Al), silver (Ag), tin (Sn), gold (Au), nickel (Ni), lead (Pb), titanium (Ti) or their alloy.

The redistribution layers 121a and 171a may be configured to perform various functions depending on design. For example, the redistribution layers 121a and 171a may include at least one of a ground pattern GND, a power pattern PWR, and a signal pattern S. The redistribution vias 121b, 122b, 171b and 172b may include, for example, at least one of ground via, a power via, and a signal via, but example embodiments are not limited thereto

The protective layers 136 and 186 are respectively formed on the insulating layers 126b and 176b, and protect the insulating layers 126b and 176b and the exposed pads 130 and 180 from an external environment. The protective layers 136 and 186 may include, for example, one or more of a thermosetting resin such as an epoxy resin, a thermoplastic resin such as polyimide, or a resin in which an inorganic filler and/or a glass fiber (glass cloth or glass fabric) is immersed in the above resins, for example, prepreg, ABF, FR-4 and BT, but example embodiments are not limited thereto For example, the protective layers 136 and 186 include, for example, an insulating resin having excellent heat resistance and flame retardancy in consideration of functional characteristics of being exposed to the outside of the package and protecting the pads 130 and 180. For example, the protective layers 136 and 186 may include a non-photosensitive resin in which an inorganic filler is immersed, but example embodiments are not limited thereto.

A connection terminal 199 is installed on the second redistribution layer structure 160. The connection terminal 199 may be, for example, in the form of a solder ball, but example embodiments are not limited thereto. The connection terminal 199 is connected to the exposed second pad 180.

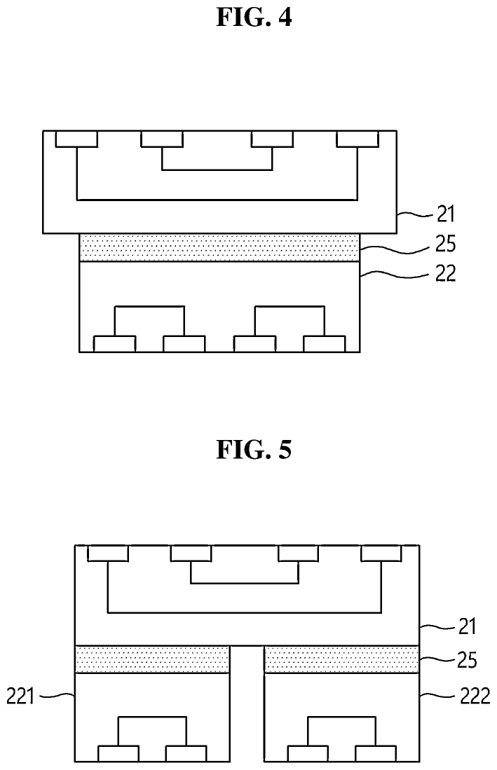

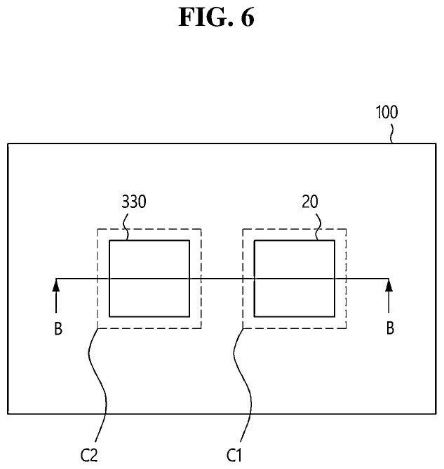

FIG. 4 is a view illustrating an example of a multi-bridge shown in FIG. 2. FIG. 5 is a view illustrating another example of a multi-bridge shown in FIG. 2. For convenience of description, the following description will be based on differences from the description made with reference to FIGS. 1 to 3.

As in the multi-bridge shown in FIG. 4, a width of the first bridge 21 and a width of the second bridge 22 may be different or substantially different from each other. The width of the first bridge 21 may be greater than the width of the second bridge 22, but example embodiments are not limited thereto.

As in the multi-bridge shown in FIG. 5, the width of the first bridge 21 is greater than that of second bridges 221 and 222. In addition, the plurality of second bridges 221 and 222 may be installed on the first bridge 21. In the drawing, the two second bridges 221 and 222 are shown, but example embodiments are not limited thereto. For example, three or more second bridges may be installed.

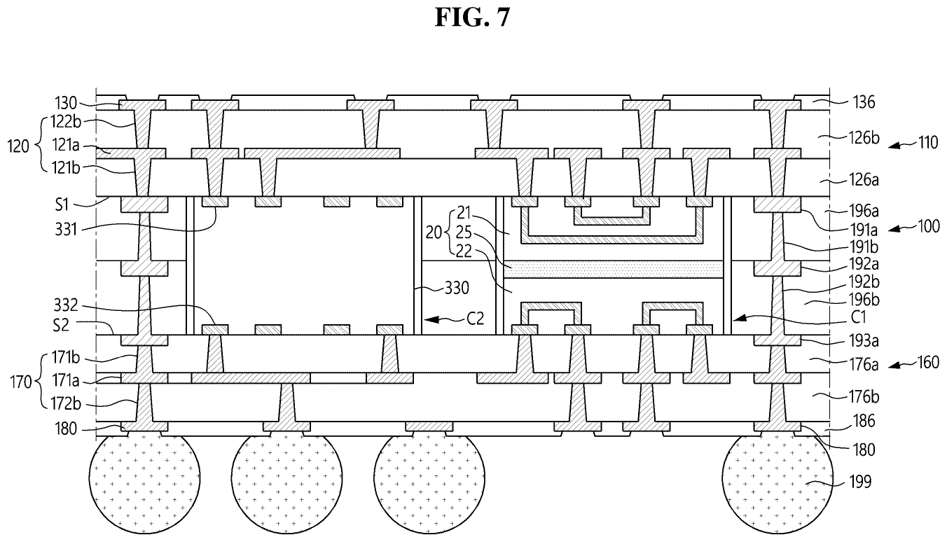

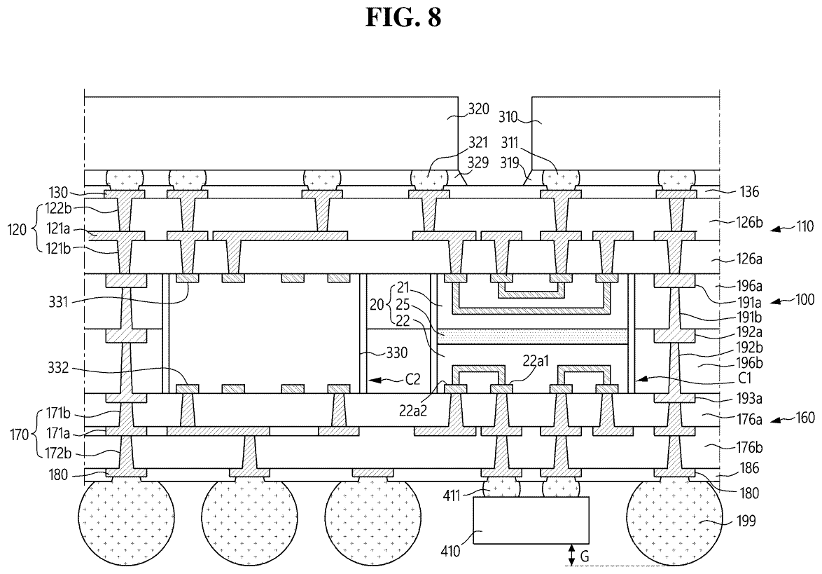

FIG. 6 is a plan view illustrating a semiconductor device according to some embodiments of the present inventive concepts. FIG. 7 is a cross-sectional view illustrating a semiconductor device, which is taken along line B-B of FIG. 6. For convenience of description, the following description will be based on differences from the description made with reference to FIGS. 1 to 3.

Referring to FIGS. 6 and 7, the semiconductor device according to some example embodiments of the present inventive concepts includes a substrate 100, a first redistribution layer structure 110, a second redistribution layer structure 160, a multi-bridge 20, and an element 330.

A first cavity C1 and a second cavity C2, which pass through the first surface S1 and the second surface S2, are formed in the substrate 100. The multi-bridge 20 is packaged in the first cavity C1, and the element 330 is packaged in the second cavity C2.

The element 330 may include one or more of a power management IC (PMIC) or an application processor (AP), but example embodiments are not limited thereto.

The element 330 includes a first chip pad 331 formed on one surface thereof, and a second chip pad 332 formed on another surface thereof. The first chip pad 331 is connected to the first pad 130 through the first connection wiring 120 of the first redistribution layer structure 110. The second chip pad 332 is connected to the second pad 180 through the second connection wiring 170 of the second redistribution layer structure 160.

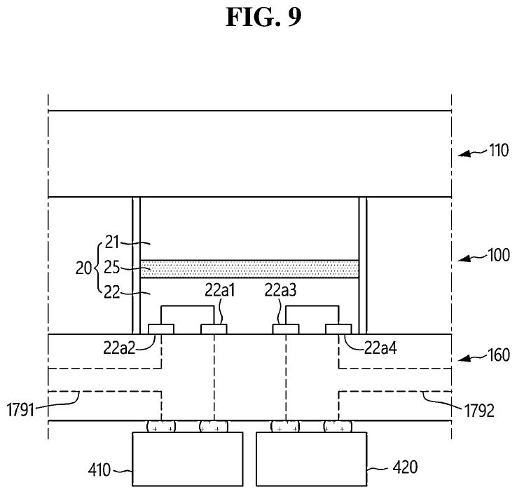

FIG. 8 is a cross-sectional view illustrating a semiconductor device according to some example embodiments of inventive concepts. For convenience of description, the following description will be based on differences from the description made with reference to FIGS. 6 and 7.

Referring to FIG. 8, in the semiconductor device according to some example embodiments of inventive concepts, a first element 310 and a second element 320 are installed on the first redistribution layer structure 110, and a component 410 is installed on the second redistribution layer structure 160.

The first element 310 is connected to a corresponding first pad 130 through a bump 311. An underfill insulator 319 is filled in a space between the first element 310 and the first redistribution layer structure 110.

The second element 320 is connected to a corresponding first pad 130 through a bump 321. An underfill insulator 329 is filled in a space between the second element 320 and the first redistribution layer structure 110.

Any one of the first element 310 and the second element 320 may be, for example, a memory device, for example, a High Bandwidth Memory (HBM) in which a plurality of memory chips are stacked, and the other one may be, for example, a processor (e.g., Graphic Processing Unit (GPU), Central Processing Unit (CPU), etc.) The first element 310 and the second element 320 may be configured to transmit and receive signals to and from each other through the first connection wiring 120 and the first bridge 21.

The component 410 is connected to a corresponding second pad 180 through a terminal (bump) 411. The component 410 may be a capacitor, for example, a multilayer ceramic capacitor (MLCC). Alternatively, the component 410 may be a resistor or an inductor.

The second bridge 22 is connected to the second connection wiring 170 of the second redistribution layer structure 160, for example, a bridge pad 22al of the second bridge 22 is connected to the terminal 411 of the component 410 through the redistribution vias 171b and 172b and the redistribution layer 171a. A bridge pad 22a2 may be connected to the redistribution layer 171a through the redistribution via 171b.

A thickness of the component 410 may be configured to be smaller than a height of a connection terminal. For example, a gap G is generated between one surface of the component 410 and a lowermost surface of the connection terminal. This gap allows the semiconductor device to be stably packaged on a printed circuit board or the like.

For example, in the semiconductor device according to some example embodiments of inventive concepts, the plurality of cavities C1 and C2 are formed in the substrate 100, the multi-bridge 20 is packaged in the first cavity C1, and the element is packaged in the second cavity C2. The first element 310 and the second element 320 directly transmit and receive signals through the first bridge 21 of the multi-bridge 20. In addition, the second redistribution layer structure and the component 410 may be connected to each other through the second bridge 22 of the multi-bridge 20. The component 410 may be disposed on a surface opposite to the first element 310 and the second element 320, such that a space may be utilized, but example embodiments are not limited thereto.

The multi-bridge 20 may be used as described above, so that various functions may be performed in the limited space, and a small form factor may be improved.

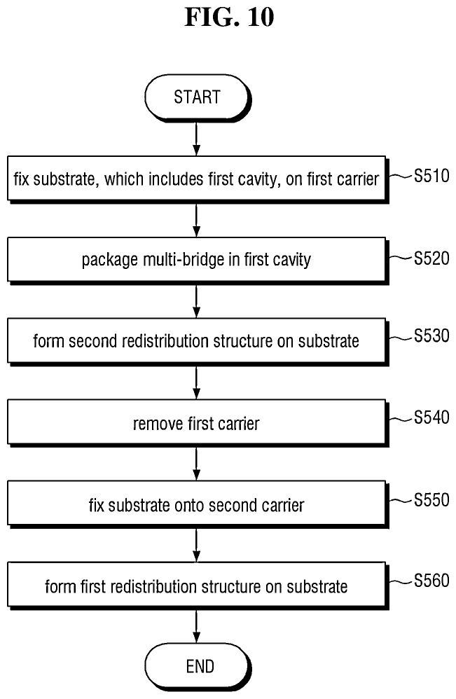

FIG. 9 is a cross-sectional view illustrating a semiconductor device according to some example embodiments of inventive concepts. The following description will be based on differences from the description made with reference to FIG. 8.

In the semiconductor device shown in FIG. 8, one component 410 is packaged on the second redistribution layer structure 160.

On the other hand, in the semiconductor device shown in FIG. 9, a plurality of components 410 and 420 are packaged on the second redistribution layer structure 160. The component 410 may be connected by a connection wiring 1791 and the other component 420 may be connected by another connection wiring 1792, but the example embodiments are not limited thereto.

The second bridge 22 may include a plurality of bridge pads 22al, 22a2, 22a3 and 22a4. As shown in FIG. 9, the bridge pad 22al and the bridge pad 22a2 may be connected to each other in the second bridge 22. The bridge pad 22al is connected to a first terminal of the component 410 through the redistribution via. The bridge pad 22a2 is connected to the second redistribution layer structure through the redistribution via. Further, the bridge pad 22a3 and the bridge pad 22a4 are connected to each other in the second bridge 22. The bridge pad 22a3 is connected to a second terminal of the component 420 through the redistribution via. The bridge pad 22a4 is connected to the redistribution layer through the redistribution via.

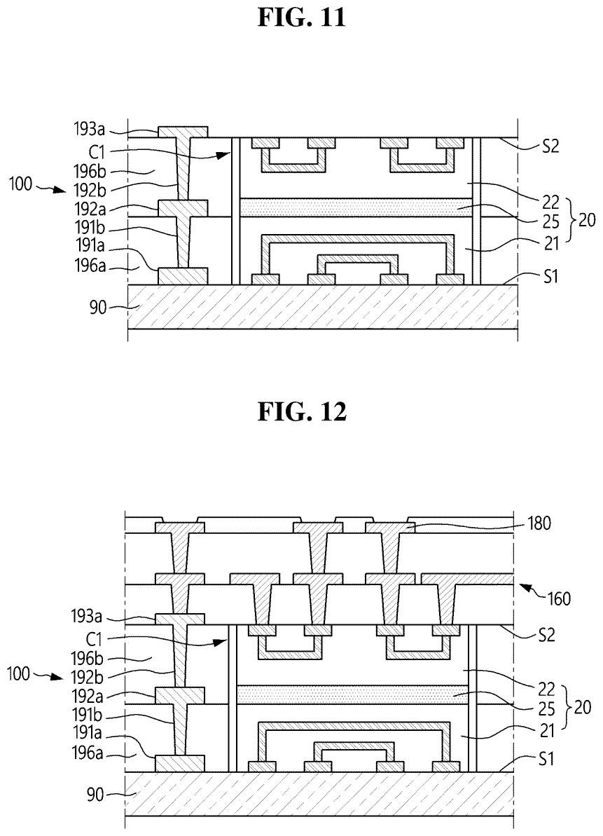

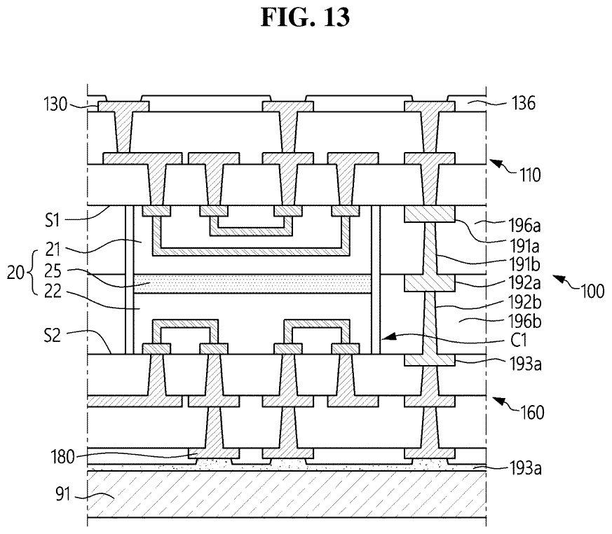

FIG. 10 is a flow chart illustrating a method for fabricating a semiconductor device according to some example embodiments of inventive concepts. FIGS. 11 to 13 are views illustrating intermediate steps to describe the method of FIG. 10. For convenience of description, the description the same or substantially the same as the description made with reference to FIGS. 1 to 9 will be omitted.

Referring to FIGS. 10 and 11, a substrate 100 is fixed onto a first carrier 90 (S510).

In detail, the substrate 100 includes a first surface S1 and a second surface S2, which face each other, and includes a first cavity C1 passing through the first surface S1 and the second surface S2. The first surface S1 is directed toward the first carrier 90.

Subsequently, a multi-bridge 20, which includes a first bridge 21 directed toward the first surface S1 and a second bridge 22 directed toward the second surface S2, is packaged in the first cavity C1 (S520).

Referring to FIGS. 10 and 12, a second redistribution layer structure 160 is formed on the second surface S2 of the substrate 100 in which the multi-bridge 20 is packaged (S530).

Next, referring to FIGS. 10 and 13, the first carrier 90 is removed (S540), and the substrate 100 is fixed onto a second carrier 91 (S550).

For example, when the substrate 100 is fixed onto the second carrier 91, the substrate 100 is turned over so that the second surface S2 is directed toward the second carrier 91. A material layer 193a for temporarily fixing the substrate 100 may be, for example, disposed between the second redistribution layer structure 160 and the second carrier 91, but example embodiments are not limited thereto.

Subsequently, a first redistribution layer structure 110 is formed on the first surface S1 of the substrate 100 (S560).

Additionally, a first element (see 310 of FIG. 8) and a second element (see 320 of FIG. 8) may be formed on the first redistribution layer structure 110 of the substrate 100. The first element 310 and the second element 320 may transmit and receive signals to and from each other through the first bridge 21 of the multi-bridge 20.

Also, the second carrier 91 may be removed, and a component MLCC (see, for example, 410 of FIG. 8) may be formed on the second redistribution layer structure 160 of the substrate 100.

Although example embodiments of inventive concepts have been described with reference to the accompanying drawings, it will be apparent to those skilled in the art that inventive concepts may be realized in various forms without being limited to the above-described example embodiments and may be embodied in other specific forms without departing from the technical spirit and essential characteristics. Thus, the above example embodiments are to be considered in all respects as illustrative and neither limiting nor restrictive.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A semiconductor device, comprising:
a substrate having a first surface and a second surface facing each other, and the substrate defining a first cavity passing through the first surface and the second surface;
a first redistribution layer structure on the first surface of the substrate;
a second redistribution layer structure on the second surface of the substrate;
a connection terminal on the second redistribution layer structure; and
a multi-bridge in the first cavity, the multi-bridge including a first bridge facing the first surface and electrically connected to the first redistribution layer structure and a second bridge facing the second surface and electrically connected to the second redistribution layer structure.

2. The semiconductor device of claim 1, further comprising:
a first element and a second element on the first redistribution layer structure, wherein the first element and the second element are configured to transmit and receive signals to and from each other through the first bridge.

3. The semiconductor device of claim 1, further comprising:
a component on the second redistribution layer structure, wherein the component is connected to the second bridge.

4. The semiconductor device of claim 3, wherein the component includes a multilayer ceramic capacitor (MLCC).

5. The semiconductor device of claim 3, wherein a thickness of the component is smaller than a height of the connection terminal.

6. The semiconductor device of claim 3, wherein the second bridge includes a first bridge pad and a second bridge pad electrically connected to each other, and
the second redistribution layer structure includes a first redistribution layer, a first redistribution via connecting the first bridge pad to the first redistribution layer and a second redistribution via connecting the second bridge pad to a first terminal of the component.

7. The semiconductor device of claim 6, wherein the second bridge further includes a third bridge pad and a fourth bridge pad, which are electrically connected to each other, and
the second redistribution layer structure includes a second redistribution layer, a third redistribution via connecting the third bridge pad to the second redistribution layer, and a fourth redistribution via connecting the fourth bridge pad to a second terminal of the component.

8. The semiconductor device of claim 1, wherein the multi-bridge further includes an adhesive film between the first bridge and the second bridge.

9. The semiconductor device of claim 1, wherein the substrate defines a second cavity passing through the first surface and the second surface, and further includes a third element packaged in the second cavity.

10. The semiconductor device of claim 9, wherein the third element includes at least one of a power management IC (PMIC) or an application processor (AP).

11. The semiconductor device of claim 10, further comprising:
a first element and a second element on the first redistribution layer structure, wherein at least one of the first element or the second element includes a plurality of stacked memory chips.

12. The semiconductor device of claim 1, wherein the substrate includes an embedded trace substrate (ETS).

13. A semiconductor device comprising:
a substrate having a first surface and a second surface facing each other, and the substrate defining a first cavity and a second cavity, the first cavity and the second cavity passing through the first and second surfaces;
a first redistribution layer structure on the first surface of the substrate;
a second redistribution layer structure on the second surface of the substrate;
a connection terminal on the second redistribution layer structure;
a multi-bridge in the first cavity, the multi-bridge including a first bridge facing the first surface and electrically connected to the first redistribution layer structure, a second bridge facing the second surface and electrically connected to the second redistribution layer structure, and an adhesive film between the first bridge and the second bridge;
first and second elements on the first redistribution layer structure, the first and second elements configured to transmit and receive signals to and from each other through the first bridge;
a component on the second redistribution layer structure and electrically connected to the second bridge; and
a third element in the second cavity.

14. The semiconductor device of claim 13, wherein the component includes a multilayer ceramic capacitor (MLCC).

15. The semiconductor device of claim 13, wherein the substrate includes an embedded trace substrate (ETS), and at least one of the first element or the second element includes a plurality of stacked memory chips.

16. The semiconductor device of claim 13, further comprising:
a bump below the first element and the second element, the first element and the second element being electrically connected to the first redistribution layer structure through the bump, and an underfill insulator being filled around the bump.

17. A method for fabricating a semiconductor device, the method comprising:
fixing a substrate onto a first carrier, the substrate having a first surface and a second surface facing each other, and the substrate defining a first cavity passing through the first surface and the second surface, the first surface facing the first carrier,
packaging a multi-bridge in the first cavity, the multi-bridge including a first bridge facing the first surface and a second bridge facing the second surface;
forming a second redistribution layer structure on the second surface of the substrate,
removing the first carrier;
fixing the substrate onto a second carrier, the second surface facing the second carrier; and
forming a first redistribution layer structure on the first surface of the substrate.

18. The method of claim 17, further comprising:
installing a first element and a second element on the first redistribution layer structure, the first and second elements being configured to transmit and receive signals to and from each other through the first bridge.

19. The method of claim 17, further comprising:
installing a component on the second redistribution layer structure, the component being connected to the second bridge.

20. The method of claim 18, wherein the component includes a multilayer ceramic capacitor (MLCC).
